(19) United States
(12) Patent Application Publication
(10) Pub. No.: US 2017/0194536 A1
(43) Pub. Date: Jul. 6, 2017

(54) METHOD OF PRODUCING AN OPTOELECTRONIC COMPONENT AND OPTOELECTRONIC COMPONENT

(71) Applicant: OSRAM Opto Semiconductors GmbH, Regensburg (DE)

(72) Inventor: Ion Stoll, Tegernheim (DE)

(21) Appl. No.: 15/313,303

(22) PCT Filed: Jun. 3, 2015
(86) PCT No.: PCT/EP2015/062364

§ 371 Date: Nov. 22, 2016

(30) Foreign Application Priority Data
Jun. 6, 2014 (DE) 10 2014 108 004.1

(51) Int. Cl. H01L 33/50; H01L 33/58; G03B 15/02; F21V 13/02; F21V 9/16; H01L 25/075; H01L 33/62

(52) U.S. Cl. CPC H01L 33/504; H01L 25/0753; H01L 33/58; H01L 33/62; F21V 13/02; F21V 9/16; G03B 15/02; H01L 2933/0041; F21Y 2115/00

(57) ABSTRACT

A method of producing an optoelectronic component includes providing an optoelectronic semiconductor chip, selecting a wavelength-converting element in dependence on a dominant wavelength of an electromagnetic radiation that can be emitted by the optoelectronic semiconductor chip, and situating the selected wavelength-converting element in a beam path of the optoelectronic semiconductor chip to form an optoelectronic arrangement, wherein the wavelength-converting element is selected such that chromaticity coordinates of an electromagnetic radiation that can be emitted by the optoelectronic arrangement lie within a specified value range of chromaticity coordinates, a peak wavelength of a blue peak of the electromagnetic radiation that can be emitted by the optoelectronic arrangement lies within a specified value range of peak wavelengths, and the value range of peak wavelengths is 438 nm to 458 nm.

### TECHNICAL FIELD

This disclosure relates to methods of producing optoelectronic components and to optoelectronic components.

### BACKGROUND

It is known to equip optoelectronic components, for example, light-emitting diode components, with wavelength-converting elements provided to convert electromagnetic radiation emitted by an optoelectronic semiconductor chip, for example, a light-emitting diode chip, of the optoelectronic component into electromagnetic radiation of other wavelengths. As a result, white light can be generated, for example, from electromagnetic radiation emitted by an optoelectronic semiconductor chip and has a wavelength in the blue region of the spectrum.

In the production of optoelectronic semiconductor chips, fluctuations occur in the electromagnetic spectra that can be emitted by the individual optoelectronic semiconductor chips. To produce optoelectronic components having similar chromaticity coordinates from optoelectronic semiconductor chips having emission spectra that deviate from one another, it is known to adjust the concentration of converter materials in wavelength-converting elements used in the optoelectronic components. However, such optoelectronic components produced from optoelectronic semiconductor chips having different emission spectra have deviations in their spectra, despite having similar chromaticity coordinates. In particular, a peak wavelength of a blue peak of the light emitted by the optoelectronic components can vary in optoelectronic components produced from optoelectronic semiconductor chips having different emission spectra.

It is known to use optoelectronic components, for example, light-emitting diode components to emit white light, as a flash light source in photographic cameras and in cellular phones having a camera function. For this purpose, it is desirable for the optoelectronic components used to have the most uniform emission spectra possible to obtain a reproducible color-rendering result without the need to provide costly color sensors.

It could therefore be helpful to provide a low cost, simple method of producing an optoelectronic component.

### SUMMARY

I provide a method of producing an optoelectronic component including providing an optoelectronic semiconductor chip, selecting a wavelength-converting element in dependence on a dominant wavelength of an electromagnetic radiation that can be emitted by the optoelectronic semiconductor chip, and situating the selected wavelength-converting element in a beam path of the optoelectronic semiconductor chip to form an optoelectronic arrangement, wherein the wavelength-converting element is selected such that chromaticity coordinates of an electromagnetic radiation that can be emitted by the optoelectronic arrangement lie within a specified value range of chromaticity coordinates, a peak wavelength of a blue peak of the electromagnetic radiation that can be emitted by the optoelectronic arrangement lies within a specified value range of peak wavelengths, and the value range of peak wavelengths is 438 nm to 458 nm.

I also provide an optoelectronic component including a first optoelectronic arrangement formed from a first optoelectronic semiconductor chip and a first wavelength-converting element situated in a beam path of the first optoelectronic semiconductor chip, and a second optoelectronic arrangement formed from a second optoelectronic semiconductor chip and a second wavelength-converting element situated in a beam path of the second optoelectronic semiconductor chip, wherein the first optoelectronic semiconductor chip emits electromagnetic radiation having a dominant wavelength from a first wavelength interval, and the second optoelectronic semiconductor chip emits electromagnetic radiation having a dominant wavelength from a second wavelength interval, chromaticity coordinates of an electromagnetic radiation that can be emitted by the first optoelectronic arrangement and chromaticity coordinates of an electromagnetic radiation that can be emitted by the second optoelectronic arrangement lie within a specified value range of chromaticity coordinates, and a peak wavelength of a blue peak of the electromagnetic radiation that can be emitted by the first optoelectronic arrangement, and a peak wavelength of a blue peak of the electromagnetic radiation that can be emitted by the second optoelectronic arrangement lie within a specified value range of peak wavelengths.

### BRIEF DESCRIPTION OF THE DRAWINGS

FIG. 1 shows an optoelectronic arrangement of a first optoelectronic component.

FIG. 2 shows a chromaticity diagram of chromaticity coordinates of electromagnetic radiation emitted by an optoelectronic component.

FIG. 3 shows a spectral diagram illustrating spectra of electromagnetic radiation emitted by optoelectronic components.

FIG. 4 shows a second optoelectronic component comprising two optoelectronic arrangements.

### LIST OF REFERENCE NUMBERS

100 First optoelectronic component
110 Optoelectronic arrangement
120 Optoelectronic semiconductor chip
121 Upper face
122 Lower face
130 Wavelength-converting element
131 Upper face
132 Lower face
133 Luminophore
134 Further luminophore
200 Chromaticity diagram
201 x-Component
202 y-Component
210 Color space
220 Chromaticity coordinates
230 Value range of the chromaticity coordinates
240 3-Step MacAdam ellipse
250 5-Step MacAdam ellipse
300 Spectral diagram
301 Wavelength
302 Intensity
310 First spectrum
311 Blue peak
312 Peak wavelength
320 Second spectrum
321 Blue peak
322 Peak wavelength
330 Third spectrum
331 Blue peak
332 Peak wavelength
340 Fourth spectrum
341 Blue peak
342 Peak wavelength
350 Value range of peak wavelengths
400 Second optoelectronic component
410 First optoelectronic arrangement
415 Second optoelectronic arrangement
420 First optoelectronic semiconductor chip
425 Second optoelectronic semiconductor chip
430 First wavelength-converting element
435 Second wavelength-converting element
440 Housing body
450 Common optical lens

### DETAILED DESCRIPTION

My method of producing an optoelectronic component includes steps of providing an optoelectronic semiconductor chip, selecting a wavelength-converting element in dependence on a dominant wavelength of an electromagnetic radiation emitted by the optoelectronic semiconductor chip, and situating the selected wavelength-converting element in the beam path of the optoelectronic semiconductor chip to form an optoelectronic arrangement. The wavelength-converting element is selected such that chromaticity coordinates of an electromagnetic radiation emitted by the optoelectronic arrangement lie within a specified value range of chromaticity coordinates. In addition, the wavelength-converting element is selected such that a peak wavelength of a blue peak of the electromagnetic radiation emitted by the optoelectronic arrangement lies within a specified value range of peak wavelengths.

Advantageously, this method makes it possible to produce an optoelectronic component having an optoelectronic arrangement that emits electromagnetic radiation of specified chromaticity coordinates and has a specified peak wavelength of a blue peak. The method therefore makes it possible to use optoelectronic semiconductor chips having emission spectra that deviate from one another. The specified chromaticity coordinates and the specified peak wavelength of the blue peak of the electromagnetic spectrum emitted by the optoelectronic arrangement of the optoelectronic component obtained by way of the method are achieved by combining the optoelectronic semiconductor chip in the optoelectronic arrangement with a wavelength-converting element tuned to a dominant wavelength of an electromagnetic radiation emitted by the optoelectronic semiconductor chip. Advantageously, the method therefore makes it possible to produce optoelectronic components having luminous characteristics very similar to one another, wherein the method makes it possible to use optoelectronic semiconductor chips having emission characteristics that deviate from one another relatively substantially. As a result, the method can be advantageously carried out at low cost.

Providing the optoelectronic semiconductor chip may refer to providing an optoelectronic semiconductor chip having a dominant wavelength of an electromagnetic radiation emitted by the optoelectronic semiconductor chip, which dominant wavelength lies anywhere between 445 nm and 460 nm. Advantageously, the method therefore makes it possible to use optoelectronic semiconductor chips having substantially varying characteristics. This advantageously allows for simple and low-cost production of the optoelectronic semiconductor chips, wherein a large portion of the produced optoelectronic semiconductor chips can be used to produce the optoelectronic components using my method.

The value range of the peak wavelengths may be the range from 438 nm to 458 nm. Advantageously, the method therefore makes it possible to produce optoelectronic components having optoelectronic arrangements designed to emit electromagnetic radiation in which a blue peak has a peak wavelength specified within narrow limits.

The value range of chromaticity coordinates may be a range of a 5-step MacAdam ellipse around specified chromaticity coordinates, preferably a range of a 3-step MacAdam ellipse around the specified chromaticity coordinates. Advantageously, the method therefore makes it possible to produce optoelectronic components having optoelectronic arrangements designed to emit electromagnetic radiation that lies at chromaticity coordinates specified within narrow limits.

A first wavelength-converting element may be selected if the dominant wavelength of the electromagnetic radiation emitted by the optoelectronic semiconductor chip lies within a first wavelength interval. A second wavelength-converting element is selected if the dominant wavelength of the electromagnetic radiation emitted by the optoelectronic semiconductor chip lies within a second wavelength interval. Advantageously, the method therefore makes it possible to easily select the wavelength-converting element in dependence on the dominant wavelength of the electromagnetic radiation emitted by the optoelectronic semiconductor chip.

The first wavelength interval may include the range from 445 nm to 450 nm. Advantageously, it has been shown that this wavelength interval of the dominant wavelength of the electromagnetic radiation emitted by the optoelectronic semiconductor chip can be covered by a standard wavelength-converting element.

The second wavelength interval may include the range from 450 nm to 460 nm. This interval of the dominant wavelength of the electromagnetic radiation emitted by the optoelectronic semiconductor chip can also be covered, advantageously, by a single wavelength-converting element.

The first wavelength-converting element may comprise a luminophore having a Lu₃(AlₓGa₁₋ₓ)₅O₁₂ host lattice. Advantageously, a wavelength-converting element comprising a luminophore having this host lattice is suitable to absorb electromagnetic radiation having a relatively short wavelength. In particular, a luminophore having a Lu₃(AlₓGa₁₋ₓ)₅O₁₂ host lattice is suitable to absorb electromagnetic radiation having a shorter wavelength than a luminophore having a Lu₃Al₅O₁₂ host lattice.

The second wavelength-converting element may comprise a luminophore having a Lu₃Al₅O₁₂ host lattice. Advantageously, a wavelength-converting element comprising a luminophore having such a host lattice is suitable to absorb electromagnetic radiation having a relatively long wavelength. In particular, a wavelength-converting element comprising a luminophore having a Lu₃Al₅O₁₂ host lattice is suitable to absorb electromagnetic radiation having a longer wavelength than a wavelength-converting element comprising a luminophore having a Lu₃(AlₓGa₁₋ₓ)₅O₁₂ host lattice.

A first optoelectronic semiconductor chip may be provided to emit electromagnetic radiation having a dominant wavelength from the first wavelength interval, and a second optoelectronic semiconductor chip may be provided to emit electromagnetic radiation having a dominant wavelength from the second wavelength interval. A first optoelectronic arrangement is formed from the first optoelectronic semiconductor chip and the first wavelength-converting element. A second optoelectronic arrangement is formed from the second optoelectronic semiconductor chip and the second wavelength-converting element. Advantageously, the method therefore makes it possible to produce multiple optoelectronic components from optoelectronic semiconductor chips having characteristics that deviate from one another, in particular emission spectra that deviate from one another. The multiple optoelectronic components obtained by the method advantageously have similar emission spectra, in particular similar chromaticity coordinates and similar peak wavelengths of their blue peaks, despite the deviations between the optoelectronic semiconductor chips.

The optoelectronic component may be formed from the first optoelectronic arrangement and the second optoelectronic arrangement. In this case, the optoelectronic component obtained by the method comprises two optoelectronic arrangements, whereby the optoelectronic component can emit electromagnetic radiation having great luminosity. Advantageously, in this optoelectronic component, electromagnetic radiations emitted by the first optoelectronic arrangement and by the second optoelectronic arrangement can be mixed with one another, whereby a white color of a light emitted by the optoelectronic component obtained by the method can be further improved.

An optoelectronic component comprises a first optoelectronic arrangement formed from a first optoelectronic semiconductor chip and a first wavelength-converting element situated in the beam path of the first optoelectronic semiconductor chip, and a second optoelectronic arrangement formed from a second optoelectronic semiconductor chip and a second wavelength-converting element situated in the beam path of the second optoelectronic semiconductor chip. The first optoelectronic semiconductor chip emits electromagnetic radiation having a dominant wavelength from a first wavelength interval. The second optoelectronic semiconductor chip emits electromagnetic radiation having a dominant wavelength from a second wavelength interval. Chromaticity coordinates of an electromagnetic radiation emitted by the first optoelectronic arrangement, and chromaticity coordinates of an electromagnetic radiation emitted by the second optoelectronic arrangement lie within a specified value range of chromaticity coordinates. A peak wavelength of a blue peak of the electromagnetic radiation emitted by the first optoelectronic arrangement, and a peak wavelength of a blue peak of the electromagnetic radiation emitted by the second optoelectronic arrangement lie within a specified value range of peak wavelengths.

Advantageously, the two optoelectronic arrangements of this optoelectronic component are therefore designed to emit electromagnetic radiation having substantially consistent chromaticity coordinates and a substantially consistent peak wavelength of a blue peak. Remaining differences in the spectra of the electromagnetic radiations emitted by the two optoelectronic arrangements of the optoelectronic component are advantageously attenuated by the superimposition of the electromagnetic radiations emitted by the two optoelectronic arrangements of the optoelectronic component. As a result, the chromaticity coordinates and the peak wavelength of a blue peak of electromagnetic radiation emitted by the optoelectronic component as a whole are advantageously specified with great accuracy. This is achieved even though the first optoelectronic semiconductor chip of the first optoelectronic arrangement and the second optoelectronic semiconductor chip of the second optoelectronic arrangement of the optoelectronic component differ in terms of the dominant wavelength of the electromagnetic radiations emitted by the two optoelectronic semiconductor chips. This advantageously makes it possible to use optoelectronic semiconductor chips whose dominant wavelength lies within the first wavelength interval, and optoelectronic semiconductor chips whose dominant wavelength lies within the second wavelength interval to produce the optoelectronic component. As a result, the optoelectronic component can be advantageously produced at low cost.

A common optical lens may be situated in the beam path of the first optoelectronic arrangement and in the beam path of the second optoelectronic arrangement. The common optical lens can thereby effect a mixing of electromagnetic radiation emitted by the first optoelectronic arrangement with electromagnetic radiation emitted by the second optoelectronic arrangement. As a result, possible deviations in the spectra of the electromagnetic radiations emitted by the first optoelectronic arrangement and by the second optoelectronic arrangement are attenuated.

The first optoelectronic semiconductor chip and the second optoelectronic semiconductor chip may be connected in series. This advantageously allows for a particularly simple control of the optoelectronic semiconductor chip of the optoelectronic component. In addition, due to the serial connection of the optoelectronic semiconductor chips of the optoelectronic component, it is ensured that the same amperage always flows through the first optoelectronic semiconductor chip and the second optoelectronic semiconductor chip.

The first optoelectronic semiconductor chip may emit electromagnetic radiation having a dominant wavelength between 445 nm and 452.5 nm. The second optoelectronic semiconductor chip may emit electromagnetic radiation having a dominant wavelength between 447.5 nm and 460 nm. Advantageously, it is therefore possible to use optoelectronic semiconductor chips having a large spread of the dominant wavelength of the electromagnetic radiation emitted by the optoelectronic semiconductor chips to produce the optoelectronic component. As a result, low-cost production of the optoelectronic component is possible.

The first wavelength-converting element may comprise a luminophore having a Lu₃(AlₓGa₁₋ₓ)₅O₁₂ host lattice. The second wavelength-converting element comprises a luminophore having a Lu₃Al₅O₁₂ host lattice. Advantageously, the wavelength-converting elements of the optoelectronic arrangements of the optoelectronic component can therefore compensate for differences in the dominant wavelengths of the optoelectronic semiconductor chips of the optoelectronic arrangements. In this case, advantage is taken of the fact that the first wavelength-converting element, which comprises a luminophore having a Lu₃(AlₓGa₁₋ₓ)₅O₁₂ host lattice, has a shorter-wavelength absorption maximum than the second wavelength-converting element comprising a luminophore having the Lu₃Al₅O₁₂ host lattice.

The first wavelength-converting element may comprise a further luminophore. Alternatively or additionally, the second wavelength-converting element may comprise a further luminophore. The further luminophore can be used to generate electromagnetic radiation from a further wavelength range. As a result, the optoelectronic component can be advantageously designed to emitting electromagnetic radiation having fractions from a broad region of the spectrum.

The further luminophore may emit electromagnetic radiation having a wavelength from the red region of the spectrum. As a result, the light emitted by the optoelectronic component can advantageously have a white color. As a result, the optoelectronic component is suited for use, for example, as a flash light in a photographic camera or a cellular phone.

The above-described properties, features, and advantages and the manner in which they are achieved will become clearer and easier to understand in combination with the description of the examples described in greater detail in combination with the drawings.

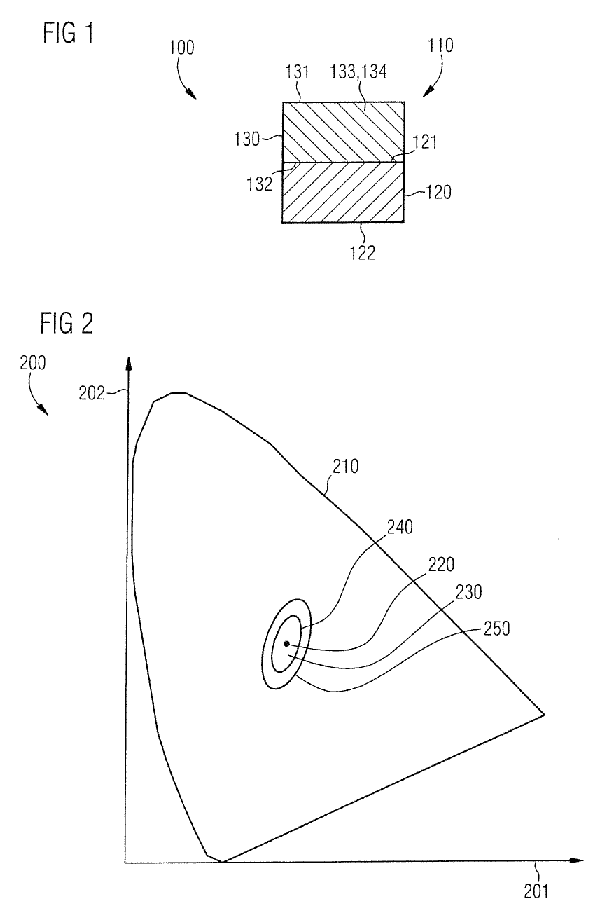

FIG. 1 shows a very highly schematicized, sectional side view of a first optoelectronic component 100. The first optoelectronic component 100 generates electromagnetic radiation, in particular visible light. The first optoelectronic component 100 can be, for example, a light-emitting diode component. The first optoelectronic component 100 can be used, for example, as a flash light source in a photographic camera. In particular, the first optoelectronic component 100 can be used as a flash light source of a photographic camera built into a cellular phone.

The schematic representation from FIG. 1 simply shows an optoelectronic arrangement 110 of the first optoelectronic component 100. The first optoelectronic component 100 can comprise further components, however, which are not shown in FIG. 1, for example, a housing, an optically imaging system such as an optical lens, and electrical connection devices.

The optoelectronic arrangement 110 comprises an optoelectronic semiconductor chip 120 and a wavelength-converting element 130. The optoelectronic semiconductor chip 120 has an upper face 121 and a lower face 122 opposite the upper face 121. The wavelength-converting element 130 has an upper face 131 and a lower face 132 opposite the upper face 131. The wavelength-converting element 130 is situated over the optoelectronic semiconductor chip 120 such that the lower face 132 of the wavelength-converting element 130 faces the upper face 121 of the optoelectronic semiconductor chip 120. In the example of the optoelectronic arrangement 110 depicted in FIG. 1, the lower face 132 of the wavelength-converting element 130 directly contacts the upper face 121 of the optoelectronic semiconductor chip 120. It is also possible, however, to arrange the wavelength-converting element 130 spaced apart from the optoelectronic semiconductor chip 120.

The wavelength-converting element 130 can be positioned on the optoelectronic semiconductor chip 120, for example, by layer transfer, volume encapsulation, spray coating, electrophoresis, or by another method. In this case, it is possible to initially produce the wavelength-converting element 130 separately from the optoelectronic semiconductor chip 120 and to then position it on the optoelectronic semiconductor chip 120. Alternatively, it is possible to produce the wavelength-converting element 130 directly on the optoelectronic semiconductor chip 120.

The optoelectronic semiconductor chip 120 can be, for example, a light-emitting diode chip (LED chip). The optoelectronic semiconductor chip 120 emits electromagnetic radiation. The upper face 121 of the optoelectronic semiconductor chip 120 forms a radiation emission face of the optoelectronic semiconductor chip 120. The wavelength-converting element 130 of the optoelectronic arrangement 110 is therefore situated in the beam path of the electromagnetic radiation emitted by the optoelectronic semiconductor chip 120 of the optoelectronic arrangement 110.

The optoelectronic semiconductor chip 120 of the optoelectronic arrangement 110 of the first optoelectronic component 100 emits electromagnetic radiation having a distribution of wavelengths dependent on the optoelectronic semiconductor chip 120. The spectrum of the electromagnetic radiation that can be emitted by the optoelectronic semiconductor chip 120 can be characterized by a dominant wavelength. The dominant wavelength is a measure of a color impression made upon a human observer by the electromagnetic radiation that can be emitted by the optoelectronic semiconductor chip 120. The dominant wavelength is a way of describing a polychromatic light mixture in terms of the monochromatic light that evokes a similar perception of hue. The dominant wavelength can therefore be referred to as a hue-equivalent wavelength. The dominant wavelength of the electromagnetic radiation that can be emitted by the optoelectronic semiconductor chip 120 can be determined by measurement.

Optoelectronic semiconductor chips are usually sorted after their production into categories (chip bins) dependent on their dominant wavelength. Each of these categories can include optoelectronic semiconductor chips having a dominant wavelength from a specified wavelength interval of, for example, 2.5 nm or 5 nm in width.

The optoelectronic semiconductor chip 120 of the optoelectronic arrangement 110 of the first optoelectronic component 100 from FIG. 1 can come from one of multiple adjacent categories (chip bins). For example, the optoelectronic semiconductor chip 120 for emission of electromagnetic radiation can have a dominant wavelength between 445 and 460 nm. The optoelectronic semiconductor chip 120 then emits electromagnetic radiation (visible light) having a dominant wavelength from the violet to blue region of the spectrum.

The wavelength-converting element 130 of the optoelectronic arrangement 110 of the first optoelectronic component 100 converts a portion of the electromagnetic radiation emitted by the optoelectronic semiconductor chip 120 of the optoelectronic arrangement 110 of the first optoelectronic component 100 into electromagnetic radiation of other wavelengths. As a result, the electromagnetic radiation emitted by the optoelectronic arrangement 110 of the first optoelectronic component 100 as a whole comprises portions of a larger wavelength spectrum than the electromagnetic radiation emitted by the optoelectronic semiconductor chip 120 itself. The electromagnetic radiation emitted by the optoelectronic arrangement 110 as a whole can therefore be referred to as white light.

If multiple first optoelectronic components 100 are produced, the dominant wavelengths of the electromagnetic radiations emitted by the optoelectronic semiconductor chips 120 of the first optoelectronic components 100 can differ from one another, as described, since the optoelectronic semiconductor chips 120 of the multiple first optoelectronic components 100 can come from different categories (chip bins). Nevertheless, the optoelectronic arrangements 110 of the multiple first optoelectronic components 100 should emit electromagnetic radiation having as similar spectra as possible to permit the best and most reproducible color rendering possible when the first optoelectronic components 100 are used as flash light sources. This is achieved by adapting the wavelength-converting element 130 of the optoelectronic arrangement 110 in every first optoelectronic component 100 to the dominant wavelength of the electromagnetic radiation emitted by the optoelectronic semiconductor chip 120 of the optoelectronic arrangement 110 of the particular first optoelectronic component 100. In the production of the first optoelectronic components 100, the wavelength-converting element 130 is selected, in each case, in dependence on the dominant wavelength of the electromagnetic radiation emitted by the particular optoelectronic semiconductor chip 120 and is situated in the beam path of the optoelectronic semiconductor chip 120 to form the particular optoelectronic arrangement 110.

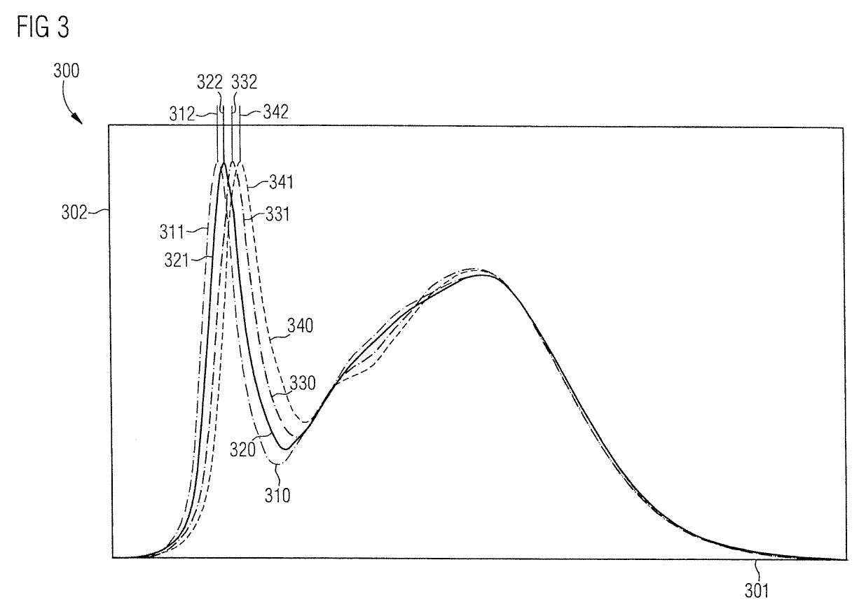

The requirement that the electromagnetic radiation emitted by the optoelectronic arrangement 110 should have as similar a spectrum as possible in every first optoelectronic component 100 means, in particular, that chromaticity coordinates of an electromagnetic radiation emitted by the particular optoelectronic arrangement 110 lie within a specified value range of chromaticity coordinates, and a peak wavelength of a blue peak of the electromagnetic radiation emitted by the particular optoelectronic arrangement 110 lies within a specified value range of peak wavelengths. This is explained in the following with reference to FIGS. 2 and 3.

FIG. 2 shows a schematic representation of a chromaticity diagram 200 in the CIE standard valence system. An x-component 201 of colors is shown on a horizontal axis and a y-component 202 of colors is shown on a vertical axis. A color space 210 is formed by a bounded area of the chromaticity diagram 200.

The spectra of the electromagnetic radiations emitted by the optoelectronic arrangements 110 of all first optoelectronic components 100 should lie within a value range of chromaticity coordinates 230 around specified chromaticity coordinates 220 in the color space 210. The chromacitity coordinates 220 can have, for example, a value of the x-component 201 of 0.35 and a value of the y-component 202 of 0.36, although they can also be located at any other point in the color space 210.

The value range of the chromaticity coordinates 230 can be an area of the color space 210 around the chromaticity coordinates 220 bounded by specified coordinates. In the case in which the chromaticity coordinates 220 have the value 0.36 for the x-component 201 and the value 0.36 for the y-component 202, the value range of the chromaticity coordinates 230 can be bounded, for example, by the following coordinate pairs of the x-component 201 and the y-component 202: 0.3322/0.32; 0.3326/0.375; 0.3552/0.3319; 0.3658/0.3921.

Alternatively, the value range of the chromaticity coordinates 230 can also be specified by a MacAdam ellipse around the chromaticity coordinates 220, for example, by a 5-step MacAdam ellipse 250 or, preferably by a 3-step MacAdam ellipse 240. The value ranges of the chromaticity coordinates bounded by the MacAdam ellipses 240, 250 indicate chromaticity coordinates that evoke the same color impression as the chromaticity coordinates 220 in a defined percentage of observers. In this case, the percentage with regard to the 3-step MacAdam ellipse 240 is greater than with the 5-step MacAdam ellipse 250.

FIG. 3 shows a schematic representation of a spectral diagram 300. A wavelength 301 is plotted on a horizontal axis, wherein the wavelength 301 increases from left to right. An intensity 302, which increases from bottom to top, is plotted on a vertical axis. The intensity can be defined, for example, as a relative radiation efficiency.

A first spectrum 310, a second spectrum 320, a third spectrum 330, and a fourth spectrum 340 are represented in the spectral diagram 300 from FIG. 3. The spectra 310, 320, 330, 340 are spectra of electromagnetic radiations emitted by the optoelectronic arrangements 110 of four different first optoelectronic components 100. The optoelectronic semiconductor chips 120 of the optoelectronic arrangements 110 of these four first optoelectronic components 100 emit electromagnetic radiation having different dominant wavelengths in each case. For example, the optoelectronic semiconductor chip 120 of the optoelectronic arrangement 110 emitting the first spectrum 310 can have a dominant wavelength of 447.5 nm. The optoelectronic semiconductor chip 120 of the optoelectronic arrangement 110 emitting the second spectrum 320 can have a dominant wavelength, for example, of 450 nm. The optoelectronic semiconductor chip 120 of the optoelectronic arrangement 110 emitting the third spectrum 330 can have a dominant wavelength, for example, of 455 nm. The optoelectronic semiconductor chip 120 of the optoelectronic arrangement 110 emitting the fourth spectrum 340 can have a dominant wavelength, for example, of 457.5 nm.

Each of the spectra 310, 320, 330, 340 has a blue peak, i.e., a relative intensity maximum in the blue or violet region of the spectrum. In addition, the spectra 310, 320, 330, 340 in the example shown each have a further relative maximum in the orange or red region of the spectrum. The first spectrum 310 has a blue peak 311. The second spectrum 320 has a blue peak 321. The third spectrum 330 has a blue peak 331. The fourth spectrum 340 has a blue peak 341.

The maximum of the blue peaks 311, 321, 331, 341 is reached at a peak wavelength in each case. The peak wavelength is therefore the wavelength at which the particular blue peak 311, 321, 331, 341 reaches its maximum. The blue peak 311 of the first spectrum 310 reaches its maximum at a peak wavelength 312. The blue peak 321 of the second spectrum 320 reaches its maximum at a peak wavelength 322. The blue peak 331 of the third spectrum 330 reaches its maximum at a peak wavelength 332. The blue peak 341 of the fourth spectrum 340 reaches its maximum at a peak wavelength 342.

The peak wavelengths 312, 322, 332, 342 of all spectra 310, 320, 330, 340 depicted in FIG. 3 lie within a value range of peak wavelengths 350. The value range of peak wavelengths 350 can be, for example, the range from 438 nm to 458 nm. Therefore, the peak wavelengths 312, 322, 332, 342 of the blue peaks 311, 321, 331, 341 of the spectra 310, 320, 330, 340 of the multiple first optoelectronic components 100 advantageously all lie within the narrow value range of peak wavelengths 350 despite the different dominant wavelengths of the optoelectronic semiconductor chips 120 of the multiple first optoelectronic components 100.

The wavelength-converting element 130 of the optoelectronic arrangement 110 of the first optoelectronic component 100 from FIG. 1 comprises an embedded luminophore 133. The luminophore 133 absorbs electromagnetic radiation having a wavelength from a first region of the spectrum and, subsequently, emits electromagnetic radiation having a wavelength from a second region of the spectrum. The second region of the spectrum can in particular lie within the green region of the spectrum or can include a portion of the green region of the spectrum. In addition, the wavelength-converting element 130 of the optoelectronic arrangement 110 of the first optoelectronic component 100 can comprise a further luminophore 134 that absorbs electromagnetic radiation having a wavelength from a specified region of the spectrum and, subsequently, emits electromagnetic radiation having a wavelength from a third region of the spectrum. The third region of the spectrum can lie, for example, in the orange or red region of the spectrum or can include a portion of the orange or red region of the spectrum. The further luminophore 134 can be, for example, an Eu²⁺-doped nitride, for example, CaAlSiN₃:Eu²⁺ or (Ca, Ba, Sr)₂Si₅N₈:Eu²⁺, an Eu²⁺-doped sulfide, an Eu²⁺-doped SiAlON or an Eu²⁺-doped Si—ON.

In addition to the luminophore 130 and the further luminophore 134, the wavelength-converting element 130 can comprise even further luminophores.

It has already been stated that the wavelength-converting element 130 of the optoelectronic arrangement 110 of the first optoelectronic component 100 is tuned to the dominant wavelength of the electromagnetic radiation emitted by the optoelectronic semiconductor chip 120 of the optoelectronic arrangement 110 of the first optoelectronic component 100 to achieve the effect that the chromaticity coordinates of the electromagnetic radiation emitted by the optoelectronic arrangement 110 lie within the value range of the chromaticity coordinates 230 for every first optoelectronic component 100, and the peak wavelength of the blue peak of the spectrum of the electromagnetic radiation emitted by the optoelectronic arrangement 110 lies within the value range of the peak wavelengths 350 for every first optoelectronic component 100. Tuning the wavelength-converting element 130 to the dominant wavelength of the optoelectronic semiconductor chip 120 can take place such that different wavelength-converting elements are produced and the wavelength-converting element 130 used to produce the optoelectronic arrangement 110 is selected from the palette of the available wavelength-converting elements during the production of the optoelectronic arrangement 110 of the first optoelectronic component 100 in dependence on the dominant wavelength of the optoelectronic semiconductor chip 120 used to produce the optoelectronic arrangement 110.

The different wavelength-converting elements can differ, in particular, in that the luminophore 133 in the different wavelength-converting elements differs. For example, the luminophore 133 in the different wavelength-converting elements can have a different host lattice.

In one example, the luminophore 133 can comprise a Ce³⁺-doped Lu₃(AlₓGa₁₋ₓ)₅O₁₂ host lattice, wherein x has a value not equal to 1. In this case, the luminophore 133 can have an absorption maximum in the wavelength range between 428 nm and 446 nm. Electromagnetic radiation emitted by the luminophore 133 can then have a peak wavelength, for example, between 525 nm and 545 nm and a dominant wavelength between 555 nm and 565 nm.

Alternatively, the luminophore 133 can comprise a Ce³⁺-doped Lu₃Al₅O₁₂ host lattice. In this case, the luminophore 133 can have an absorption maximum in the range between 438 nm and 460 nm. Electromagnetic radiation emitted by the luminophore 133 can then have a peak wavelength between 535 nm and 555 nm and a dominant wavelength between 555 nm and 565 nm.

If the optoelectronic semiconductor chip 120 used to produce the optoelectronic arrangement 110 of the first optoelectronic component 100 emits electromagnetic radiation having a dominant wavelength between 445 nm and 452.5 nm, the wavelength-converting element 130 used to produce the optoelectronic arrangement 110 can be selected such that the luminophore 133 comprises a Lu₃(AlₓGa₁₋ₓ)₅O₁₂ host lattice. The peak wavelength of the blue peak of the electromagnetic radiation which can be emitted by the optoelectronic arrangement 110 of the first optoelectronic component 100 can lie between 438 nm and 450 nm, for example, in this case.

If the optoelectronic semiconductor chip 120 used to produce the optoelectronic arrangement 110 of the first optoelectronic component 100 emits electromagnetic radiation having a dominant wavelength from the range between 447.5 nm and 460 nm, the wavelength-converting element 130 used to produce the optoelectronic arrangement 110 of the first optoelectronic component 100 can be selected such that the luminophore 133 comprises a Lu₃Al₅O₁₂ host lattice. In this case, the peak wavelength of the blue peak of the electromagnetic radiation emitted by the optoelectronic arrangement 110 of the first optoelectronic component 100 can lie within the range between 446 nm and 458 nm, for example.

In this method, the wavelength-converting element 130 can therefore be selected either having the luminophore 133 comprising a Lu₃(AlₓGa₁₋ₓ)₅O₁₂ host lattice or the luminophore 133 comprising a Lu₃Al₅O₁₂ host lattice in the case in which the dominant wavelength of the emittable electromagnetic radiation of the optoelectronic semiconductor chip 120 used to produce the optoelectronic arrangement 110 lies within the range between 447.5 nm and 452.5 nm. Alternatively, however, a wavelength-converting element 130 comprising the luminophore 133 mentioned first can also always be selected in the case of a dominant wavelength of the optoelectronic semiconductor chip 120 of up to 450 nm, and a wavelength-converting element 130 comprising the luminophore 133 mentioned second can also always be selected in the case of a dominant wavelength of the optoelectronic semiconductor chip 120 of more than 450 nm. Different limits of the wavelength ranges of the dominant wavelength can also be selected, of course.

To produce multiple first optoelectronic components 100, a wavelength-converting element 130 is selected according to the stated criteria, depending, in each case, on the dominant wavelength of the optoelectronic semiconductor chip 120 used to produce the optoelectronic arrangement 110 of the particular first optoelectronic component 100, and is situated in the beam path of the optoelectronic semiconductor chip 120 to produce the optoelectronic arrangement 110 of the particular first optoelectronic component 100.

In the first optoelectronic components 100 comprising the optoelectronic arrangements 110 that emit the spectra 310, 320 depicted in the spectral diagram 300 from FIG. 3, the wavelength-converting element 130 comprising the luminophore 133 having a Lu₃(AlₓGa₁₋ₓ)₅O₁₂ host lattice in each case can be selected. In the first optoelectronic components 100 whose optoelectronic arrangements 110 emit the third spectrum 330 and the fourth spectrum 340, the wavelength-converting element 130 can comprise a luminophore 133 having a Lu₃Al₅O₁₂ host lattice.

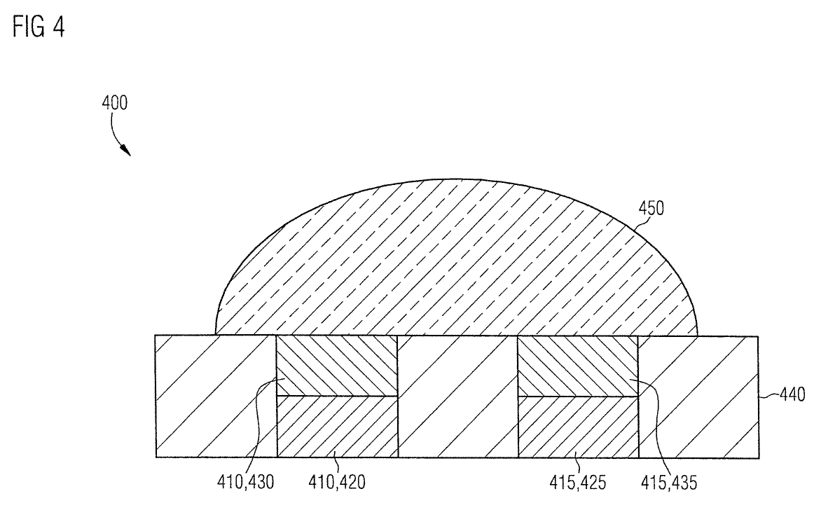

FIG. 4 shows a schematic, sectional side view of a second optoelectronic component 400. The second optoelectronic component 400 can be used, for example, as a flash light source in a photographic camera or a similar device. The second optoelectronic component 400 can comprise components in addition to the components represented in FIG. 4, for example, electrical connecting devices.

The second optoelectronic component 400 comprises a first optoelectronic arrangement 410 and a second optoelectronic arrangement 415. The first optoelectronic arrangement 410 and the second optoelectronic arrangement 415 are each designed similar to the optoelectronic arrangement 110 of the first optoelectronic component 100 from FIG. 1 and can be produced using the above-described method. The first optoelectronic arrangement 410 comprises a first optoelectronic semiconductor chip 420 and a first wavelength-converting element 430 situated in the beam path of the first optoelectronic semiconductor chip 420. The second optoelectronic arrangement 415 comprises a second optoelectronic semiconductor chip 425 and a second wavelength-converting element 435 situated in the beam path of the second optoelectronic semiconductor chip 425.

The first optoelectronic semiconductor chip 420 of the first optoelectronic arrangement 410 of the second optoelectronic component 400 emits electromagnetic radiation having a dominant wavelength from a first wavelength interval. The second optoelectronic semiconductor chip 425 of the second optoelectronic arrangement 415 of the second optoelectronic component 400 emits electromagnetic radiation having a dominant wavelength from a second wavelength interval. The first wavelength interval can be, for example, the range from 445 nm to 450 nm or can include this range. The second wavelength interval can be, for example, the range from 450 nm to 460 nm or can include this range.

The first wavelength-converting element 430 of the first optoelectronic arrangement 410 of the second optoelectronic component 400 comprises a luminophore 133 having a first host lattice, for example, a luminophore 133 comprising a Lu₃(AlₓGa₁₋ₓ)₅O₁₂ host lattice, wherein x is not equal to 1. The second wavelength-converting element 435 of the second optoelectronic arrangement 415 of the second optoelectronic component 400 comprises a luminophore 133 having a second host lattice, for example, a luminophore 133 having a Lu₃Al₅O₁₂ host lattice.

The first optoelectronic arrangement 410 and the second optoelectronic arrangement 415 of the second optoelectronic component 400 are situated in a housing body 440 of the second optoelectronic component 400. The housing body 440, for example, may be a molded article, wherein the first optoelectronic arrangement 410 and the second optoelectronic arrangement 415 are embedded in the housing body 440 designed as a molded article. The housing body 440 of the second optoelectronic component 400 can also have a different design, however.

The second optoelectronic component 400 further comprises a common optical lens 450 situated in the beam path or in the light path of the first optoelectronic arrangement 410 and of the second optoelectronic arrangement 415 of the second optoelectronic component 400. The common optical lens 450 can mix electromagnetic radiation generated by the first optoelectronic arrangement 410 with electromagnetic radiation generated by the second optoelectronic arrangement 415. In addition, the common optical lens 450 can be used to form beams of the electromagnetic radiation generated by the second optoelectronic component 400. The common optical lens 450 can also be dispensed with, however.

Due to mixing of the electromagnetic radiation emitted by the first optoelectronic arrangement 410 and by the second optoelectronic arrangement 415, which mixing can be achieved by the second optoelectronic component 400, the second optoelectronic component 400, as a whole, emits electromagnetic radiation having a spectrum that is a mixture of the individual spectra of electromagnetic radiations emitted by the first optoelectronic arrangement 410 and by the second optoelectronic arrangement 415. As a result, any differences still remaining in the total spectrum of electromagnetic radiation emitted by the second optoelectronic component 400 are leveled, despite the already existing, great similarity of the spectra of the electromagnetic radiation emitted by the first optoelectronic arrangement 410 and the electromagnetic radiation emitted by the second optoelectronic arrangement 415. Therefore, multiple correspondingly designed, second optoelectronic components 400 have very similar spectra of the electromagnetic radiations generated by the components. As a result, the second optoelectronic component 400 is particularly well suited for use as a flash light source.

The first optoelectronic semiconductor chip 420 of the first optoelectronic arrangement 410 of the second optoelectronic component 400 and the second optoelectronic semiconductor chip 425 of the second optoelectronic arrangement 415 of the second optoelectronic component 400 can connect in series. As a result, it can be ensured that the same amperage always flows through the first optoelectronic semiconductor chip 420 and the second optoelectronic semiconductor chip 425 of the second optoelectronic component 400 during operation of the second optoelectronic component 400. It is also possible, however, to arrange the first optoelectronic semiconductor chip 420 and the second optoelectronic semiconductor chip 425 to electrically connect in parallel or to design these to be individually controllable.

My components and methods are illustrated and described in greater detail with reference to the preferred examples. This disclosure is not limited to the disclosed examples, however. Instead, other variations can be derived therefrom by those skilled in the art, without departing from the scope of protection of the appended claims.

This application claims priority of DE 10 2014 108 004.1, the subject matter of which is hereby incorporated by reference.

1-18. (canceled)

19. A method of producing an optoelectronic component comprising:
providing an optoelectronic semiconductor chip;
selecting a wavelength-converting element in dependence on a dominant wavelength of an electromagnetic radiation that can be emitted by the optoelectronic semiconductor chip; and
situating the selected wavelength-converting element in a beam path of the optoelectronic semiconductor chip to form an optoelectronic arrangement,
wherein the wavelength-converting element is selected such that chromaticity coordinates of an electromagnetic radiation that can be emitted by the optoelectronic arrangement lie within a specified value range of chromaticity coordinates,
a peak wavelength of a blue peak of the electromagnetic radiation that can be emitted by the optoelectronic arrangement lies within a specified value range of peak wavelengths, and
the value range of peak wavelengths is 438 nm to 458 nm.

20. The method as claimed in claim 19, wherein providing the optoelectronic semiconductor chip provides an optoelectronic semiconductor chip having a dominant wavelength of an electromagnetic radiation that can be emitted by the optoelectronic semiconductor chip, which dominant wavelength lies between 445 nm and 460 nm.

21. The method according to claim 19, wherein the value range of chromaticity coordinates is a range of a 5-step MacAdam ellipse around specified chromaticity coordinates or a range of a 3-step MacAdam ellipse around the specified chromaticity coordinates.

22. The method according to claim 19, wherein a first wavelength-converting element is selected if the dominant wavelength of the electromagnetic radiation that can be emitted by the optoelectronic semiconductor chip lies within a first wavelength interval, and
a second wavelength-converting element is selected if the dominant wavelength of the electromagnetic radiation that can be emitted by the optoelectronic semiconductor chip lies within a second wavelength interval.

23. The method according to claim 22, wherein the first wavelength interval includes 445 nm to 450 nm.

24. The method according to claim 22, wherein the second wavelength interval includes 450 nm to 460 nm.

25. The method according to claim 22, wherein the first wavelength-converting element comprises a luminophore having a Lu₃(AlₓGa₁₋ₓ)₅O₁₂ host lattice.

26. The method according to claim 22, wherein the second wavelength-converting element comprises a luminophore having a Lu₃Al₅O₁₂ host lattice.

27. The method according to claim 22, wherein a first optoelectronic semiconductor chip is provided to emit electromagnetic radiation having a dominant wavelength from the first wavelength interval, and a second optoelectronic semiconductor chip is provided to emit electromagnetic radiation having a dominant wavelength from the second wavelength interval, and
a first optoelectronic arrangement is formed from the first optoelectronic semiconductor chip and the first wavelength-converting element, and a second optoelectronic arrangement is formed from the second optoelectronic semiconductor chip and the second wavelength-converting element.

28. The method according to claim 27, wherein the optoelectronic component is formed from the first optoelectronic arrangement and from the second optoelectronic arrangement.

29. An optoelectronic component comprising:
a first optoelectronic arrangement formed from a first optoelectronic semiconductor chip and a first wavelength-converting element situated in a beam path of the first optoelectronic semiconductor chip; and
a second optoelectronic arrangement formed from a second optoelectronic semiconductor chip and a second wavelength-converting element situated in a beam path of the second optoelectronic semiconductor chip,
wherein the first optoelectronic semiconductor chip emits electromagnetic radiation having a dominant wavelength from a first wavelength interval, and the second optoelectronic semiconductor chip emits electromagnetic radiation having a dominant wavelength from a second wavelength interval,
chromaticity coordinates of an electromagnetic radiation that can be emitted by the first optoelectronic arrangement and chromaticity coordinates of an electromagnetic radiation that can be emitted by the second optoelectronic arrangement lie within a specified value range of chromaticity coordinates, and
a peak wavelength of a blue peak of the electromagnetic radiation that can be emitted by the first optoelectronic arrangement, and a peak wavelength of a blue peak of the electromagnetic radiation that can be emitted by the second optoelectronic arrangement lie within a specified value range of peak wavelengths.

30. The optoelectronic component according to claim 25, wherein a common optical lens is situated in the beam path of the first optoelectronic arrangement and in the beam path of the second optoelectronic arrangement.

31. The optoelectronic component according to claim 29, wherein the first optoelectronic semiconductor chip and the second optoelectronic semiconductor chip are connected in series.

32. The optoelectronic component according to claim 29, wherein the first optoelectronic semiconductor chip emits electromagnetic radiation having a dominant wavelength between 445 nm and 452.5 nm, and the second optoelectronic semiconductor chip emits electromagnetic radiation having a dominant wavelength between 447.5 nm and 460 nm.

33. The optoelectronic component according to claim 22, wherein the first wavelength-converting element comprises a luminophore having a Lu₃(AlₓGa₁₋ₓ)₅O₁₂ host lattice, and the second wavelength-converting element comprises a luminophore having a Lu₃Al₅O₁₂ host lattice.

34. The optoelectronic component according to claim 33, wherein the first wavelength-converting element comprises a further luminophore and/or the second wavelength-converting element comprises a further luminophore.

35. The optoelectronic component according to claim 34, wherein the further luminophore emits electromagnetic radiation having a wavelength from the red region of the spectrum.
